(19) United States
(12) Patent Application Publication
(10) Pub. No.: US 2026/0045284 A1
(43) Pub. Date: Feb. 12, 2026

(54) TECHNIQUES FOR CLOCK COORDINATION WITH REDUCED POWER AND LATENCY AT A MEMORY SYSTEM

(71) Applicant: Micron Technology, Inc., Boise, ID (US)

(72) Inventors: Parthasarathy Gajapathy, Mckinney, TX (US); Ming-Bo Liu, Plano, TX (US); David R. Brown, Allen, TX (US)

(21) Appl. No.: 19/271,652

(22) Filed: Jul. 16, 2025

Related U.S. Application Data
(60) Provisional application No. 63/681,653, filed on Aug. 9, 2024.

(51) Int. Cl. G11C 7/22; G11C 7/10

(52) U.S. Cl. CPC G11C 7/222; G11C 7/1093; G11C 7/225

(57) ABSTRACT

Methods, systems, and devices for techniques for clock coordination with reduced power and latency at a memory system are described. The described techniques provide for a memory system to delay the initiation of a decoding clock at the origin of a clock tree. For example, the memory system may initiate a command/address (CA) clock at a first time corresponding to reception of a CS signal, and may initiate the decoding clock at a second time following the first time by one or more unit intervals of the internal clock. Further, the described techniques provide for the memory system to buffer a first set of CA and buffer a second set of the CA bits according to respective unit intervals of the CA clock such that all the CA bits may be decoded at the decoder according to a single edge of the decoding clock.

### CROSS REFERENCE

The present Application for Patent claims priority to U.S. Patent Application No. 63/681,653 by Gajapathy et al., entitled “TECHNIQUES FOR CLOCK COORDINATION WITH REDUCED POWER AND LATENCY AT A MEMORY SYSTEM,” filed Aug. 9, 2024, which is assigned to the assignee hereof, and which is expressly incorporated by reference in its entirety herein.

### TECHNICAL FIELD

The following relates to one or more systems for memory, including techniques for clock coordination with reduced power and latency at a memory system.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports techniques for clock coordination with reduced power and latency at a memory system in accordance with examples as disclosed herein.

FIG. 2 shows an example of a system that supports techniques for clock coordination with reduced power and latency at a memory system in accordance with examples as disclosed herein.

FIG. 3 shows an example of a clock diagram that supports techniques for clock coordination with reduced power and latency at a memory system in accordance with examples as disclosed herein.

FIG. 4 shows an example of a clock diagram that supports techniques for clock coordination with reduced power and latency at a memory system in accordance with examples as disclosed herein.

FIG. 5 shows a block diagram of a memory system that supports techniques for clock coordination with reduced power and latency at a memory system in accordance with examples as disclosed herein.

FIGS. 6 and 7 show flowcharts illustrating methods that support techniques for clock coordination with reduced power and latency at a memory system in accordance with examples as disclosed herein.

### DETAILED DESCRIPTION

Memory systems may be provided in accordance with various configurations that support operating one or more components to manage received commands. In some configurations, a memory system may utilize one or more clock signals to maintain alignment between components, in the time domain, when decoding and executing commands received from a host system. For example, the memory system may receive a clock signal from the host system (e.g., an external clock (CLK)) and a chip select (CS) signal associated with a command for the memory system, and the memory system may initiate an internal clock corresponding to the received clock (e.g., an internal clock (CLK Int)) based on receiving the CS signal. The internal clock may be part of a clock tree for the memory system (e.g., may be an origin of the clock tree). A clock tree may refer to a specific arrangement of conductive lines and buffers used to distribute a clock signal from a clock source (e.g., a clock pad or an internal clock) to other components that use the clock signal in a circuit. Clock trees are used by synchronous circuits to trigger operations. The design of the clock tree can impact the performance, power consumption, and reliability of the system. The main goal of a clock tree is to minimize skew and insertion delay, ensuring that the clock signal arrives at all parts of the circuit when expected. The memory system may utilize one or more clock signals associated with branches of the clock tree to support operating one or more components of the memory system associated with receiving and decoding the command. For example, in accordance with the internal clock and the CS signal, the memory system may initiate a first clock signal configured to cause components of a command/address (CA) data path to buffer CA bits associated with the command (e.g., the first clock may be a CA clock, which may be referred to as CLK CA). Additionally, in accordance with the internal clock, the memory system may initiate a second clock configured to cause a decoder to decode the CA bits of the command (e.g., the second clock may be a decoding clock, which may be referred to as CLK M). In some examples, the first clock and the second clock may be initiated simultaneously, such as in response to receiving the CS signal.

In some examples, a first clock path associated with the CA clock may be relatively long in comparison to a second clock path associated with the decoding clock. For example, the first clock path may include accessing multiple CA pads (e.g., 14 different CA pads, or another quantity of CA pads) distributed throughout the memory system. Accessing such pads may result in a misalignment between the CA clock and the decoding clock, for example due to propagation delays associated with the CA clock reaching each CA pad. To facilitate aligning the decoding clock at the decoder at a time when the CA bits are received at the decoder, the memory system may delay the decoding clock using a delay circuit (e.g., configured to loop the decoding clock until the CA bits are ready at the decoder). However, delaying the decoding clock using the delay circuit may incur relatively high power consumption at the memory system. Additionally, or alternatively, the memory system may be configured to decode the command at the decoder using two unit intervals of the decoding clock, such as when the command includes more CA bits than there are CA pads at the memory system. However, at relatively high clock speeds (e.g., double data rate 6 (DDR6) speeds), a time delay boundary between the unit intervals of the decoding clock may introduce significant latency at the memory system.

Techniques described herein may provide for a memory system to reduce power expenditure associated with aligning a decoding clock with the arrival of CA bits at a decoder while maintaining the alignment. In some examples, the memory system may delay the initiation of the decoding clock at the origin of the clock tree branch associated with the decoding clock. For example, the memory system may initiate the CA clock at a first time corresponding to reception of a CS signal, and may initiate the decoding clock at a second time following the first time by one or more unit intervals of the internal clock. By delaying the initiation of the decoding clock, the memory system may reduce a duration that the decoding clock is delayed via a delay circuit, thereby reducing power expenditure at the memory system. Further, the techniques described herein may provide for the memory system to eliminate the time delay boundary associated with decoding the CA bits over two unit intervals of the decoding clock. For example, the memory system may support buffering a first set of the CA bits according to first unit intervals of the CA clock, buffering a second set of the CA bits according to second unit intervals of the CA clock, and receiving each set of CA bits at the decoder such that all the CA bits may be decoded at the decoder according to a single edge of the decoding clock.

In addition to applicability in memory systems as described herein, techniques for clock coordination with reduced power and latency may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing power expenditure and latency associated with command decoding, which may decrease processing or latency times, improve response times, or otherwise improve user experience, among other benefits.

In addition to applicability in memory systems as described herein, techniques for clock coordination with reduced power and latency may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing power expenditure associated with decoding commands, which may extend the life of electronic devices and thereby reduce electronic waste, among other benefits.

In addition to applicability in memory systems as described herein, techniques for clock coordination with reduced power and latency may be generally implemented to support edge computing applications. Edge computing is a distributed computing paradigm that brings computation and data storage closer to the sources of data than traditional cloud services. As the use of edge computing to provide computing, storage, and networking services at locations that are geographically closer to end users increases, many devices and systems may benefit from improved processing, performance, and storage at edge devices. For example, increasing memory density, capacity, and processing power of edge devices may decrease a reliance on the devices to remote computing or devices, which may otherwise increase latency of operations performed at the devices. Implementing the techniques described herein may support edge computing techniques by improving command decoding response times associated with edge computing devices, among other benefits.

Features of the disclosure are illustrated and described in the context of systems. Features of the disclosure are further illustrated and described in the context of clock diagrams, a block diagram, and flowcharts.

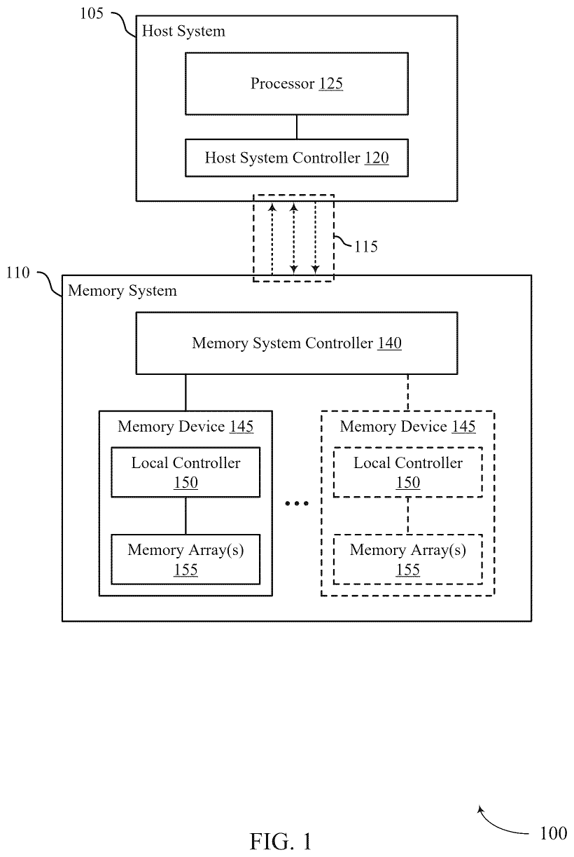

FIG. 1 illustrates an example of a system 100 that supports techniques for clock coordination with reduced power and latency at a memory system in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

Signaling may be communicated over the channels 115 using single data rate (SDR) signaling or double data rate (DDR) signaling, among other rates (e.g., relative to a clock signal). In SDR signaling, one modulation symbol (e.g., signal level) of a signal may be registered for each clock cycle (e.g., on a rising edge or a falling edge of a clock signal). In DDR signaling, two modulation symbols of a signal may be registered for each clock cycle (e.g., on both a rising edge and a falling edge of a clock signal).

A memory system 110 may utilize one or more clock signals to maintain alignment between components, in the time domain, when decoding and executing commands received from a host system 105. For example, the memory system 110 may receive a clock signal from the host system 105 (e.g., an external clock CLK) and a CS signal associated with a command for the memory system 110, and the memory system 110 may initiate an internal clock (e.g., CLK Int) corresponding to the received clock based on receiving the CS signal. The internal clock may define an origin of a clock tree, and the memory system 110 may utilize one or more clock signals associated with branches of the clock tree to support operating one or more components of the memory system 110 associated with receiving and decoding the command. For example, in accordance with the internal clock and the CS signal, the memory system 110 may initiate a first clock signal configured to cause components of a CA data path to buffer CA bits associated with the command (e.g., the first clock may be a CA clock, which may be referred to as CLK CA). Additionally, in accordance with the internal clock, the memory system may initiate a second clock configured to cause a decoder to decode the CA bits of the command (e.g., the second clock may be a decoding clock, which may be referred to as CLK M). In some examples, the first clock and the second clock may be initiated simultaneously, such as in response to receiving the CS signal.

In some examples, a first clock path associated with the CA clock may be relatively long in comparison to a second clock path associated with the decoding clock. For example, the first clock path may include accessing multiple CA pads (e.g., 14 different CA pads, or another quantity of CA pads) distributed throughout the memory system 110. Accessing such pads may result in a misalignment between the CA clock and the decoding clock, for example due to propagation delays associated with the CA clock reaching each CA pad. To facilitate aligning the decoding clock at the decoder at a time when the CA bits are received at the decoder, the memory system 110 (e.g., the memory system controller 140) may delay the decoding clock using a delay circuit (e.g., configured to loop the decoding clock until the CA bits are ready at the decoder). However, delaying the decoding clock using the delay circuit may incur relatively high power expenditure at the memory system 110. Additionally, or alternatively, the memory system 110 may be configured to decode the command at the decoder using two unit intervals of the decoding clock, such as when the command includes more CA bits than there are CA pads available at the memory system 110. However, at relatively high clock speeds (e.g., DDR6 speeds), a time delay boundary between the unit intervals of the decoding clock may introduce significant latency at the memory system 110.

Techniques described herein may provide for a memory system 110 to reduce power expenditure associated with aligning a decoding clock with the arrival of CA bits at a decoder while maintaining the alignment. In some examples, the memory system 110 may delay the initiation of the decoding clock at the origin of the clock tree branch associated with the decoding clock. For example, the memory system 110 may initiate the CA clock at a first time corresponding to reception of a CS signal, and may initiate the decoding clock at a second time following the first time by one or more unit intervals of the internal clock. By delaying the initiation of the decoding clock, the memory system 110 may reduce a duration that the decoding clock is delayed via a delay circuit, thereby reducing power expenditure at the memory system 110. Further, the techniques described herein may provide for the memory system 110 to eliminate the time delay boundary associated with decoding the CA bits over two unit intervals of the decoding clock. For example, the memory system 110 may support buffering a first set of the CA bits according to first unit intervals of the CA clock, buffering a second set of the CA bits according to second unit intervals of the CA clock, and receiving each set of CA bits at the decoder such that all the CA bits of the command may be decoded at the decoder according to a single edge of the decoding clock.

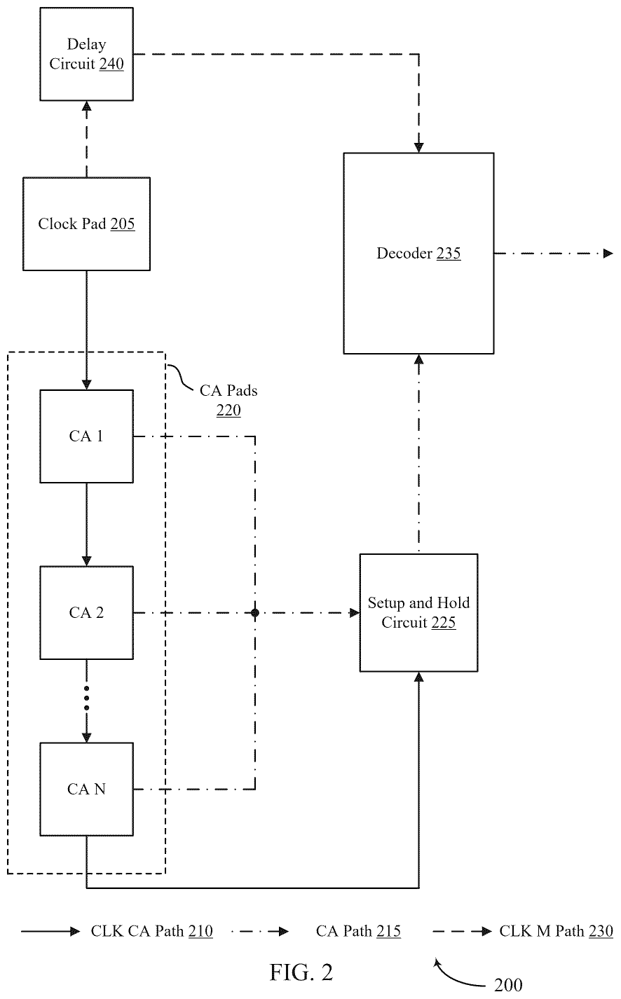

FIG. 2 illustrates an example of a system 200 that supports techniques for clock coordination with reduced power and latency at a memory system in accordance with examples as disclosed herein. The system 200 may implement, or be implemented by, one or more aspects of the system 100. For example, the system 200 illustrates and example of components and signal paths (e.g., conductive paths) included in a memory system 110 described with reference to FIG. 1. In some examples, the system 200 may support the memory system 110 decoding CA bits associated with a command according to one or more clock signals, where the one or more clock signals may be aligned by the memory system 110 in accordance with reduced power consumption, reduced latency, or both (e.g., in comparison to techniques different than those described herein).

The memory system 110 may include a clock pad 205 configured to receive a clock signal (e.g., a CLK received from a host system 105) and may be configured to initiate or otherwise facilitate the initiation of one or more clock signals to be used by the memory system 110. For example, the clock pad 205 may be associated with a clock input buffer of the memory system 110 and may support initiating an internal clock CLK Int (e.g., a gated clock) corresponding to the received CLK (e.g., the CLK Int may run at a frequency similar to the CLK). In some cases, the CLK Int may be an example of a clock signal distributed using a clock tree. The CLK Int may support operating one or more clocks of the memory system 110. The one or more clocks of the memory system 110 may include clocks associated with respective signal paths and configured to facilitate operations of respective components of the memory system 110. In some cases, the one or more clocks may each support the memory system 110 performing an operation, such as a decoding operation in response to receiving a command from the host system 105. For example, in response to receiving a CS signal (e.g., identifying a CS_n pin or flag at a low value), the memory system 110 may initiate (e.g., wake), via the clock pad 205, the one or more clocks to support decoding the command.

As an example, the clock pad 205 may support initiating a CLK CA associated with a CLK CA path 210 (e.g., a first clock path, a first conductive channel within the memory system 110). In some cases, the CLK CA may be configured to cause one or more components coupled with the CLK CA path 210 to perform operations. The CLK CA path 210 may be coupled with components of a CA path 215 and the CLK CA may be configured to cause the components of the CA path 215 to buffer multiple CA bits associated with a received command. For example, the CLK CA path 210 may route the CLK CA through a set of CA pads 220, where each CA pad 220 may be configured to receive a CA bit of the command (e.g., from the host system 105 via a CA channel) and buffer the received CA bit in response to receiving the CLK CA. It should be noted that the memory system 110 may include any quantity of CA pads 220 arranged in any configuration, and is not limited to the example illustrated by the system 200 (e.g., N may be any integer quantity and the CA pads 220 may be distributed throughout the memory system 110 according to any configuration). In some cases, each CA pad 220 may buffer a bit by transferring the bit (e.g., via the CA path 215 in accordance with one or more unit intervals of the CLK CA) to a setup and hold circuit 225. Additionally, or alternatively, each CA pad 220 may be associated with a respective setup and hold circuit 225 (e.g., the memory system 110 may include N setup and hold circuits 225 to buffer respective bits from each of the N CA pads 220). In some examples, the CLK CA may facilitate the operation of the setup and hold circuit(s) 225 (e.g., the CLK CA path 210 may couple with the setup and hold circuit(s) 225).

As another example, the clock pad 205 may support initiating a CLK M associated with a CLK M path 230 (e.g., a second clock path, a second conductive channel within the memory system 110). In some cases, the CLK M may be configured to cause a decoder 235 to decode the multiple CA bits received via the CA pads 220 (e.g., the decoder 235 may be coupled with the CLK M path 230). For example, the decoder 235 may receive the CA bits from the setup and hold circuit 225 and may decode the CA bits according to one or more unit intervals of the CLK M. In the examples described herein, a unit interval may indicate a single edge of a clock (e.g., either a rising edge or a falling edge may be a unit interval) or may indicate a cycle of a clock (e.g., a combination of a rising edge and a falling edge may be a unit interval). The decoder 235 may be configured to transfer the decoded command to other components of the memory system 110 configured to execute the command.

In some examples, a physical length of the CLK M path 230 may be shorter than a physical length of the CLK CA path 210, which may result in misalignment between the CLK M facilitating the operations of the decoder 235 and the CA bits being ready at the decoder 235. For example, due to propagation delays associated with reaching each CA pad 220 (e.g., the CLK CA path 210 may route the CLK CA throughout a substantial portion of the memory system 110), the CLK M may reach the decoder 235 prior to the CA bits being ready at the decoder 235 (based just on the propagation delays in the circuit). Accordingly, the memory system 110 may input the CLK M to a delay circuit 240, which may be configured to delay (e.g., loop, cycle, gate) the CLK M until the CA bits are ready at the decoder 235, and thereby facilitate synchronized operations of both components of the CA path 215 and the decoder 235. However, delaying the CLK M using the delay circuit 240 may incur relatively higher power expenditure at the memory system 110, which may reduce or otherwise limit performance of the memory system. Additionally, or alternatively, the memory system 110 may support decoding the CA bits at the decoder 235 according to multiple clock cycles (e.g., two unit intervals). For example, if the command includes more CA bits than there are CA pads 220, the decoder 235 may decode a first portion of the CA bits (corresponding to a first bit output at each CA pad 220) according to a first edge of the CLK M and may decode a second portion of the CA bits (corresponding to a second bit output at one or more CA pads 220) according to a second edge of the CLK M. However, at relatively higher operating speeds (e.g., DDR6 speeds), a time delay boundary between the clock cycles may introduce significant latency at the memory system 110.

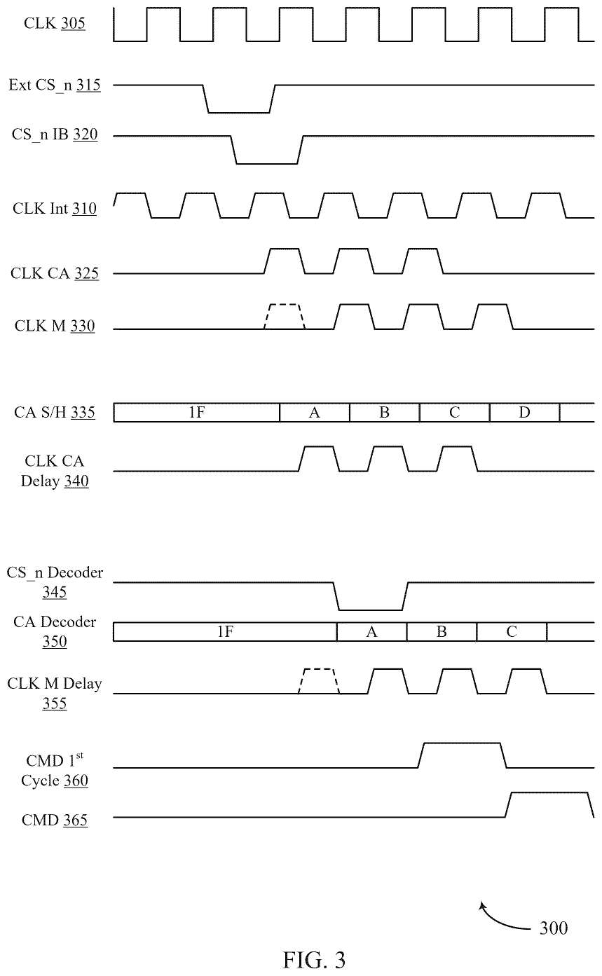

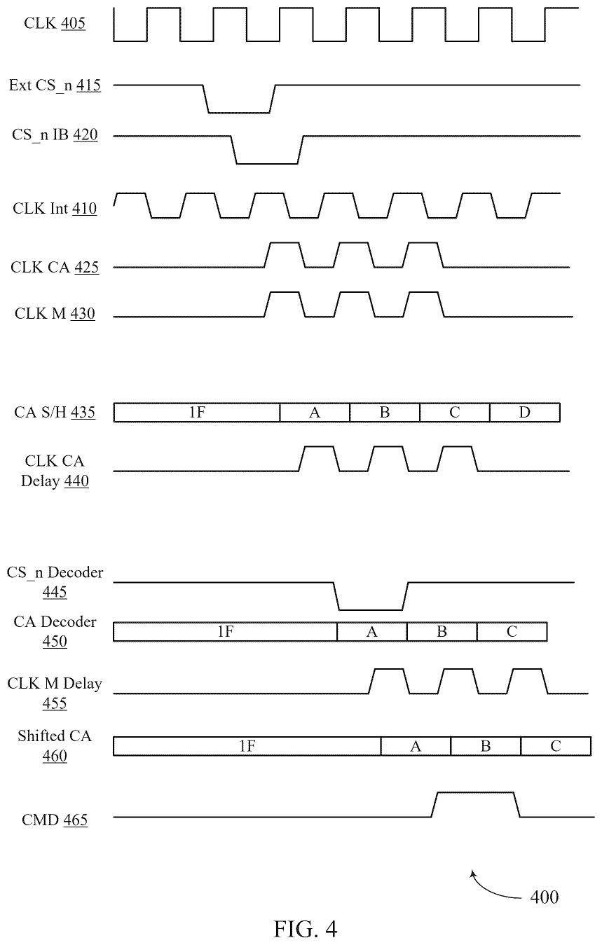

As described herein, the memory system 110 may delay initiating the CLK M to reduce power expenditure associated with aligning the CLK M using the delay circuit 240. For example, the clock pad 205 may support initiating the CLK M after initiating the CLK CA by one or more unit intervals of the CLK Int, which may reduce a duration that the CLK M is delayed via the delay circuit 240, thereby reducing power expenditure while maintaining the clock alignment (e.g., as described in greater detail with respect to FIG. 3). Further, to eliminate the time delay boundary associated with decoding the CA bits over multiple unit intervals, the memory system 110 may support collecting all the CA bits at the setup and hold circuit 225 before inputting the CA bits to the decoder 235 (e.g., as described in greater detail with respect to FIG. 4). Such techniques may improve performance of the memory system 110 when receiving and decoding commands by reducing power expenditure and latency associated with aligning clock signals and decoding CA bits.

FIG. 3 shows an example of a clock diagram 300 that supports techniques for clock coordination with reduced power and latency at a memory system in accordance with examples as disclosed herein. The clock diagram 300 may implement, or be implemented by, one or more aspects of the systems 100 and 200. For example, the clock diagram 300 illustrates an example of various clocks and components operated by a memory system 110, which may be an example of a memory system 110 described with reference to FIGS. 1 and 2. In some examples, the clock diagram 300 may support the memory system 110 maintaining an alignment between a decoding clock and CA bits arriving at a decoder while reducing a duration that the decoding clock is delayed via a delay circuit, which may be examples of corresponding aspects described with reference to FIG. 2. For example, the clock diagram 300 illustrates an example of a decoding clock being initiated one or more unit intervals after a CA clock, which may be contrasted with other systems, where the decoding clock and the CA clock may be initiated simultaneously (e.g., as illustrated by FIG. 4). The clock diagram 300 may support additional clocks, stages of clocks, component operations, or any combination thereof, and is not limited to the example illustrated by FIG. 3.

The memory system 110 may receive a CLK 305 from a host system 105, which may support the memory system 110 identifying an operating speed associated with the host system 105. For example, the memory system 110 may receive the CLK 305, from the host system 105, at the clock pad 205 described with reference to FIG. 2. The memory system 110 may receive the CLK 305 at a clock input buffer of the memory system 110 and may initiate an internal clock CLK Int 310 (e.g., a free running clock at an output of the clock input buffer, which may be an output of the clock pad 205 described with reference to FIG. 2) that corresponds to the CLK 305. In some cases, the memory system 110 may gate the CLK Int 310 (e.g., the memory system may not use or may ignore the CLK Int 310) until the memory system 110 receives an incoming active command, which may be indicated by a CS signal. For example, the memory system 110 may receive an external CS signal Ext CS_n 315, which may be received at an external pad of the memory system 110 and may indicate or be associated with a command from a host system 105 (e.g., the Ext CS_n 315 may transition to a low state to indicate an upcoming command for the memory system 110). The memory system 110 may pass the CS signal through a CS input buffer and may identify a CS_n IB 320 at the output of the CS input buffer.

In some cases, based on identifying the CS_n IB 320 in the low state, the memory system 110 may release the gated CLK Int 310 and may initiate one or more clocks in accordance with the CLK Int 310 (e.g., the CLK Int 310 may be applied to setup and hold circuitry associated with the one or more clocks in accordance with the CS_n IB 320 being low). In some cases, the one or more clocks initiated in response to the CS signal may be associated with decoding the command associated with the CS signal. For example, the memory system 110 may initiate a CLK CA 325 (e.g., a clock corresponding to a CA pin of the memory system 110) in response to the CS_n IB 320 going low, where the CLK CA 325 may correspond to a first branch of a clock tree originating from the CLK Int 310. The CLK CA 325 may be configured to cause one or more components of a CA path to buffer CA bits received via a CA channel, where the CA path may correspond to the CA path 215 as described with reference to FIG. 2. For example, with reference to FIG. 2, the CLK CA 325 may travel along the CLK CA path 210 to cause the CS pads 220 along the CA path 215 to buffer CA bits. In some cases, to prevent significant power consumption associated with running the CLK CA 325 for an entire command burst, the memory system 110 may toggle the CLK CA 325 to cycle according to a count of the CLK Int 310 (e.g., the CLK CA 325 may be toggled for three cycles of the CLK Int 310 in the example illustrated by FIG. 3).

Additionally, or alternatively, the memory system 110 may initiate a CLK M 330 (e.g., a clock corresponding to a decoding clock pin of the memory system 110) in response to the CS_n IB 320 going low. In some implementations, the memory system 110 may initiate the CLK M 330 simultaneously with initiating the CLK CA 325, for example at a first rising edge of the CLK Int 310 when the CS_n IB 320 is low. However, due to differences in clock paths associated with the CLK CA 325 and the CLK M 330, as described with reference to FIG. 2, initiating the CLK CA 325 and the CLK M 330 simultaneously may result in misalignment between the CLK M 330 and the CA bits arriving at a decoder (e.g., the decoder 235 described with reference to FIG. 2). For example, with reference to FIG. 2, the CLK M 330 may be initiated from the clock pad 205 and may travel along the CLK M path 230, which may be relatively shorter in comparison to the CLK CA path 210. In such examples, the memory system 110 may delay the CLK M 330 via a delay circuit (e.g., the delay circuit 240 described with reference to FIG. 2) to align the CLK M 330 and the CA bits at the decoder, which may incur significant power consumption at the memory system 110.

In accordance with techniques described herein, the memory system 110 may initiate the CLK M 330 a duration after initiating the CLK CA 325 (e.g., each clock may be initiated from the clock pad 205 at different times). For example, the memory system 110 may initiate the CLK CA 325 at a first time and may initiate the CLK M 330 at a second time after the first time, where a difference between the first time and the second time may correspond to one or more unit intervals of the CLK 305 (and the CLK Int 310). In the example illustrated by the clock diagram 300, the memory system 110 may initiate the CLK M 330 two unit intervals of the CLK 305 after initiating the CLK CA 325 (e.g., a rising edge and a falling edge of the CLK 305 in a DDR5 implementation). In some examples, the CLK Int 310, the Ext CS_n 315, the CS_n IB 320, the CLK CA 325, and the CLK M 330 may be part of a clock wakeup stage of the memory system 110.

In some cases, the memory system 110 may identify CA bits at a setup and hold circuit (e.g., based on components of the CA path buffering bits in response to the CLK CA 325), which may be represented by CA S/H 335 in the clock diagram 300. For example, with reference to FIG. 2, the CA S/H 335 may represent CA bits available at the setup and hold circuit 225 after being buffered by the CA pads 220. A set-up and hold circuit may be configured so that the data is stable and valid before and after a clock event, which can be important for the synchronous operation of the circuit. In some examples, external CA pads of the memory system 110 may input a sequence of CA bits to the setup and hold circuit (e.g., after receiving the CA bits at the external CA pads) and operation of the setup and hold circuit may be facilitated by a CLK CA delay 340. The CLK CA delay 340 may correspond to a delayed version of the CLK CA 325, and may be delayed according to a duration between receiving the CA bits at the external CA pads and inputting the CA bits to the setup and hold circuit (e.g., after the CLK CA 325 travels along the CLK CA path 210 of FIG. 2). In some examples, the CA S/H 335 and the CLK CA delay 340 may be part of a setup and hold stage of the memory system 110.

In some cases, the memory system 110 may identify a CS_n decoder 345 signal, which may indicate to decode the CA bits using a decoder. The CS_n decoder 345 signal may go low when the CA bits are available at the decoder, which may be represented by CA decoder 350 in the clock diagram 300. For example, the CA bits may be output from the setup and hold circuit to the decoder and the CS_n decoder 345 signal may go low once the CA bits are ready at the decoder. The memory system 110 may use a CLK M delay 355 to facilitate operation of the decoder, where the CLK M delay 355 may correspond to a delayed version of the CLK M 330. As described herein, delaying the initiation of the CLK M 330 (e.g., in response to the CS_n IB 320) may reduce a duration that the CLK M delay 355 is input to a delay circuit, which may reduce power consumption at the memory system 110 while still allowing for the CLK M delay 355 to be aligned at the decoder when the CA decoder 350 bits are ready. In some examples, the memory system 110 may decode the CA bits according to one or more command cycles. For example, the memory system 110 may decode a first subset of the CA bits (e.g., CA bits of box A in the clock diagram 300) according to a first edge of the CLK M delay 355, represented by CMD 1^{st} cycle 360 in the clock diagram 300, and may decode a second subset of the CA bits (e.g., CA bits of box B in the clock diagram 300) according to a second edge of the CLK M delay 355, represented by CMD 365 in the clock diagram 300. In some cases, decoding the command via two cycles may enable the memory system 110 to determine whether the command is a real time transfer (RTT) command (e.g., the first subset of CA bits may be enough to indicate an RTT command). In some examples, the CS_n decoder 345, the CA decoder 350, the CLK M delay 355, the CMD 1^{st} cycle 360, and the CMD 365 may be part of a decoding stage of the memory system 110.

FIG. 4 shows an example of a clock diagram 400 that supports techniques for clock coordination with reduced power and latency at a memory system in accordance with examples as disclosed herein. The clock diagram 400 may implement, or be implemented by, one or more aspects of the systems 100 and 200, as well as the clock diagram 300. For example, the clock diagram 400 illustrates an example of various clocks and components operated by a memory system 110, which may be an example of a memory system 110 described with reference to FIGS. 1 through 3. In some examples, the clock diagram 400 may support the memory system 110 decoding a set of CA bits associated with a command according to a single edge of a clock. For example, the clock diagram 400 illustrates an example of a set of CA bits being decoded according to a single edge of a clock, which may be contrasted with other systems, where the set of CA bits may be decoded according to multiple clock cycles (e.g., as illustrated by FIG. 3). The clock diagram 400 may support additional clocks, stages of clocks, component operations, or any combination thereof, and is not limited to the example illustrated by FIG. 4.

In some cases, the memory system 110 may receive a CLK 405 from a host system 105, may initiate or maintain a CLK Int 410 (e.g., an internal clock corresponding to the CLK 405), and may receive a CS signal from the host system 105 (e.g., a EXT CS_n 415 observed at an external CS pad of the memory system 110 and a CS_n IB 420 observed at the output of a CS input buffer of the memory system 110), which may be examples of corresponding aspects described with reference to FIG. 3. For example, the memory system may receive the CLK 405 at the clock pad 205 and may initiate (e.g., un-gate) the CLK Int 410 at an output of the clock pad 205 described with reference to FIG. 2. The memory system 110 may initiate, based on the CS signal and in accordance with the CLK Int 410, one or more clocks associated with decoding a received command (e.g., a command associated with the CS signal). For example, the memory system 110 may initiate a CLK CA 425 and a CLK M 430, which may be examples of corresponding clocks described with reference to FIG. 3. For example, with reference to FIG. 2, the CLK CA 425 may be initiated from the clock pad 205 and may follow the CLK CA path 210 and the CLK M 430 may be initiated from the clock pad 205 and may follow the CLK M path 230. In the example illustrated by the clock diagram 400, the memory system 110 may initiate the CLK CA 425 and the CLK M 430 simultaneously, though the memory system 110 may alternatively delay initiation of CLK M 430 in accordance with techniques described with reference to FIG. 3.

The memory system 110 may cause, according to one or more unit intervals of the CLK CA 425, components of a CA path (e.g., CA pads) to buffer CA bits of the command to a setup and hold circuit, represented by the CA S/H 435. For example, with reference to FIG. 2, the CLK CA 425 may follow the CLK CA path 210 to cause the CA pads 220 to buffer CA bits to the setup and hold circuit 225 (e.g., CA S/H 435 may represent bits available at the setup and hold circuit 225). In some cases, operation of the setup and hold circuit may be facilitated by a CLK CA delay 440, which may be a delayed version of the CLK CA 425 (e.g., delayed by a delay circuit or due to propagation delay associated with reaching each CA pad). The memory system 110 may identify a CS_n decoder 445 signal that indicates to operate the decoder to decode the CA bits (e.g., the decoder 235 described with reference to FIG. 2). For example, the CA bits may be received at the decoder from the setup and hold circuit, represented by a CA decoder 450, and the memory system 110 may facilitate operation of the decoder using a CLK M delay 455. The CLK M delay 455 may be a delayed version of the CLK M 430, which may be delayed using a delay circuit, by initiating the CLK M 430 after the CLK CA 425, or both. For example, the CLK M 430 may be input to the delay circuit 240 described with reference to FIG. 2, which may output the CLK M delay 455, where a duration of the delay may be based on whether the CLK M 430 is initiated simultaneously with the CLK CA 425.

In some cases, the clock diagram 400 may support the memory system decoding the CS bits of the command according to a single edge of the CLK M delay 455. For example, the CA decoder 450 may represent a first subset of CA bits buffered by CA pads in accordance with one or more first unit intervals of the CLK CA 425 and a shifted CA 460 may represented a second subset of CA bits buffer by the CA pads in accordance with one or more second unit intervals of the CLK CA 425. For example, with reference to FIG. 2, each of the CA pads 220 may buffer a first bit to the setup and hold circuit 225 at a first time according to the first unit intervals of the CLK CA 425 and one or more of the CA pads 220 may buffer a second bit to the setup and hold circuit 225 at a second time after the first time according to the second unit intervals of the CLK CA 425, such that the setup and hold circuit 225 holds all the CA bits before outputting to the decoder 235. In such examples, both the first subset and the second subset of the CA bits may be available at the decoder at the same time, thereby allowing for the memory system 110 to decode the command according to a single edge of the CLK M delay 455, represented by a CMD 465. Such techniques may mitigate latency associated with decoding the CA bits, such as eliminating a time delay boundary associated with decoding the command via two clock edges.

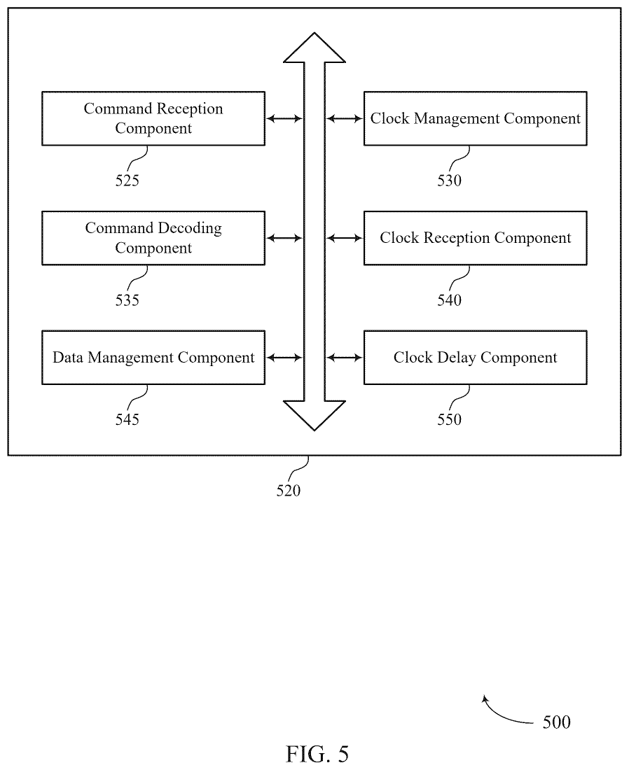

FIG. 5 shows a block diagram 500 of a memory system 520 that supports techniques for clock coordination with reduced power and latency at a memory system in accordance with examples as disclosed herein. The memory system 520 may be an example of aspects of a memory system as described with reference to FIGS. 1 through 4. The memory system 520, or various components thereof, may be an example of means for performing various aspects of techniques for clock coordination with reduced power and latency at a memory system as described herein. For example, the memory system 520 may include a command reception component 525, a clock management component 530, a command decoding component 535, a clock reception component 540, a data management component 545, a clock delay component 550, or any combination thereof. Each of these components, or components of subcomponents thereof (e.g., one or more processors, one or more memories), may communicate, directly or indirectly, with one another (e.g., via one or more buses).

The command reception component 525 may be configured as or otherwise support a means for receiving a chip select signal associated with a first command to be executed by the memory system. The clock management component 530 may be configured as or otherwise support a means for initiating, at a first time, a command/address (CA) clock configured to cause components of a CA path to buffer a plurality of CA bits received over a CA channel. In some examples, the clock management component 530 may be configured as or otherwise support a means for initiating, at a second time after the first time, a decoding clock configured to cause a decoder to decode the plurality of CA bits. The command decoding component 535 may be configured as or otherwise support a means for decoding, using the decoder and in accordance with the decoding clock, the plurality of CA bits to identify the first command.

In some examples, the clock reception component 540 may be configured as or otherwise support a means for receiving a clock associated with a host system, where a first clock path associated with the CA clock and a second clock path associated with the decoding clock include respective branches of a clock tree associated with the clock.

In some examples, a difference between the first time and the second time corresponds to one or more unit intervals of the received clock.

In some examples, the one or more unit intervals of the received clock include two unit intervals.

In some examples, the clock delay component 550 may be configured as or otherwise support a means for delaying the decoding clock using a delay circuit configured to delay the decoding clock for one or more unit intervals of the received clock, where decoding the plurality of CA bits is based at least in part on inputting the decoding clock to the delay circuit.

In some examples, to support decoding the plurality of CA bits, the command decoding component 535 may be configured as or otherwise support a means for decoding, at a third time, a first subset of the plurality of CA bits. In some examples, to support decoding the plurality of CA bits, the command decoding component 535 may be configured as or otherwise support a means for decoding, at a fourth time, a second subset of the plurality of CA bits, where a difference between the third time and the fourth time corresponds to at most two unit intervals of a clock of the memory system.

In some examples, to support decoding the plurality of CA bits, the data management component 545 may be configured as or otherwise support a means for buffering, in accordance with one or more first unit intervals of the CA clock, a first subset of the plurality of CA bits. In some examples, to support decoding the plurality of CA bits, the data management component 545 may be configured as or otherwise support a means for buffering, in accordance with one or more second unit intervals of the CA clock, a second subset of the plurality of CA bits. In some examples, to support decoding the plurality of CA bits, the command decoding component 535 may be configured as or otherwise support a means for receiving, by the decoder, the first subset and the second subset to obtain the plurality of CA bits. In some examples, to support decoding the plurality of CA bits, the command decoding component 535 may be configured as or otherwise support a means for decoding, at a third time, the plurality of CA bits, where the third time corresponds to a single edge of a clock of the memory system.

In some examples, the data management component 545 may be configured as or otherwise support a means for inputting the plurality of CA bits to a setup and hold circuit in response to initiating the CA clock. In some examples, the data management component 545 may be configured as or otherwise support a means for inputting the plurality of CA bits to the decoder in response to inputting the plurality of CA bits to the setup and hold circuit, where decoding the plurality of CA bits is in response to inputting the plurality of CA bits to the decoder.

In some examples, the command decoding component 535 may be configured as or otherwise support a means for identifying the first command based at least in part on decoding the plurality of CA bits.

In some examples, the command reception component 525 may be configured as or otherwise support a means for receiving a chip select signal associated with a first command to be executed by the memory system. In some examples, the clock management component 530 may be configured as or otherwise support a means for initiating, at a first time, a first clock configured to cause components in a first data path to buffer a plurality of bits that are associated with the first command based at least in part on receiving the chip select signal. In some examples, the clock management component 530 may be configured as or otherwise support a means for initiating, at a second time after the first time, a second clock configured to cause a decoder to decode the plurality of bits. In some examples, the command reception component 525 may be configured as or otherwise support a means for decoding, using the decoder and in accordance with the second clock, the plurality of bits to identify the first command.

In some examples, the clock reception component 540 may be configured as or otherwise support a means for receiving a third clock associated with a host system, where a first clock path associated with the first clock and a second clock path associated with the second clock include respective branches of a clock tree associated with the third clock.

In some examples, a difference between the first time and the second time corresponds to one or more unit intervals of the third clock.

In some examples, the one or more unit intervals of the third clock include two unit intervals.

In some examples, the clock delay component 550 may be configured as or otherwise support a means for delaying the second clock using a delay circuit configured to delay the second clock for one or more unit intervals of the third clock, where decoding the plurality of bits is based at least in part on inputting the second clock to the delay circuit.

In some examples, the plurality of bits include command/address bits of the first command.

In some examples, to support decoding the plurality of bits, the command decoding component 535 may be configured as or otherwise support a means for decoding, at a third time, a first subset of the plurality of bits. In some examples, to support decoding the plurality of bits, the command decoding component 535 may be configured as or otherwise support a means for decoding, at a fourth time, a second subset of the plurality of bits, where a difference between the third time and the fourth time corresponds to at most two unit intervals of a third clock of the memory system.

In some examples, to support decoding the plurality of bits, the data management component 545 may be configured as or otherwise support a means for buffering, in accordance with one or more first unit intervals of the first clock, a first subset of the plurality of bits. In some examples, to support decoding the plurality of bits, the data management component 545 may be configured as or otherwise support a means for buffering, in accordance with one or more second unit intervals of the first clock, a second subset of the plurality of bits. In some examples, to support decoding the plurality of bits, the command decoding component 535 may be configured as or otherwise support a means for receiving, by the decoder, the first subset and the second subset to obtain the plurality of bits. In some examples, to support decoding the plurality of bits, the command decoding component 535 may be configured as or otherwise support a means for decoding, at a third time, the plurality of bits, where the third time corresponds to a single edge of a third clock of the memory system.

In some examples, the data management component 545 may be configured as or otherwise support a means for inputting the plurality of bits to a setup and hold circuit in response to initiating the first clock. In some examples, the data management component 545 may be configured as or otherwise support a means for inputting the plurality of bits to the decoder in response to inputting the plurality of bits to the setup and hold circuit, where decoding the plurality of bits is in response to inputting the plurality of bits to the decoder.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

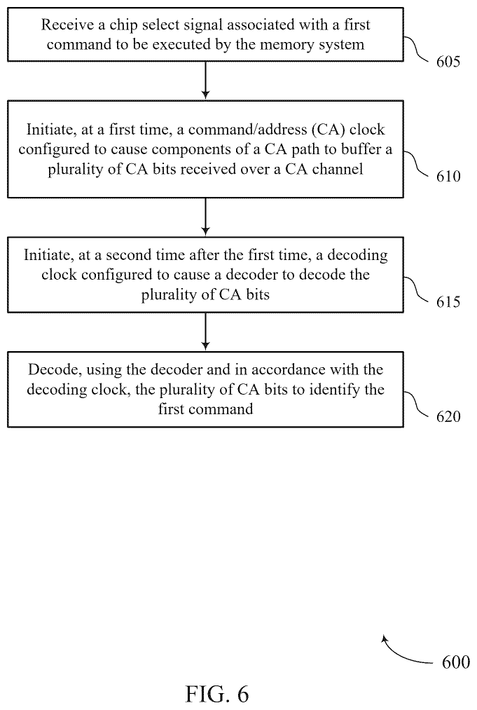

FIG. 6 shows a flowchart illustrating a method 600 that supports techniques for clock coordination with reduced power and latency at a memory system in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include receiving a chip select signal associated with a first command to be executed by the memory system. In some examples, aspects of the operations of 605 may be performed by a command reception component 525 as described with reference to FIG. 5.

At 610, the method may include initiating, at a first time, a command/address (CA) clock configured to cause components of a CA path to buffer a plurality of CA bits received over a CA channel. In some examples, aspects of the operations of 610 may be performed by a clock management component 530 as described with reference to FIG. 5.

At 615, the method may include initiating, at a second time after the first time, a decoding clock configured to cause a decoder to decode the plurality of CA bits. In some examples, aspects of the operations of 615 may be performed by a clock management component 530 as described with reference to FIG. 5.

At 620, the method may include decoding, using the decoder and in accordance with the decoding clock, the plurality of CA bits to identify the first command. In some examples, aspects of the operations of 620 may be performed by a command decoding component 535 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for receiving a chip select signal associated with a first command to be executed by the memory system; initiating, at a first time, a command/address (CA) clock configured to cause components of a CA path to buffer a plurality of CA bits received over a CA channel; initiating, at a second time after the first time, a decoding clock configured to cause a decoder to decode the plurality of CA bits; and decoding, using the decoder and in accordance with the decoding clock, the plurality of CA bits to identify the first command.
Aspect 2: The method, apparatus, or non-transitory computer-readable medium of aspect 1, further including operations, features, circuitry, logic, means, or instructions, or any combination thereof for receiving a clock associated with a host system, where a first clock path associated with the CA clock and a second clock path associated with the decoding clock include respective branches of a clock tree associated with the clock.
Aspect 3: The method, apparatus, or non-transitory computer-readable medium of aspect 2, where a difference between the first time and the second time corresponds to one or more unit intervals of the received clock.
Aspect 4: The method, apparatus, or non-transitory computer-readable medium of aspect 3, where the one or more unit intervals of the received clock include two unit intervals.
Aspect 5: The method, apparatus, or non-transitory computer-readable medium of any of aspects 2 through 4, further including operations, features, circuitry, logic, means, or instructions, or any combination thereof for delaying the decoding clock using a delay circuit configured to delay the decoding clock for one or more unit intervals of the received clock, where decoding the plurality of CA bits is based at least in part on inputting the decoding clock to the delay circuit.
Aspect 6: The method, apparatus, or non-transitory computer-readable medium of any of aspects 1 through 5, where decoding the plurality of CA bits includes operations, features, circuitry, logic, means, or instructions, or any combination thereof for decoding, at a third time, a first subset of the plurality of CA bits and decoding, at a fourth time, a second subset of the plurality of CA bits, where a difference between the third time and the fourth time corresponds to at most two unit intervals of a clock of the memory system.
Aspect 7: The method, apparatus, or non-transitory computer-readable medium of any of aspects 1 through 6, where decoding the plurality of CA bits includes operations, features, circuitry, logic, means, or instructions, or any combination thereof for buffering, in accordance with one or more first unit intervals of the CA clock, a first subset of the plurality of CA bits; buffering, in accordance with one or more second unit intervals of the CA clock, a second subset of the plurality of CA bits; receiving, by the decoder, the first subset and the second subset to obtain the plurality of CA bits; and decoding, at a third time, the plurality of CA bits, where the third time corresponds to a single edge of a clock of the memory system.
Aspect 8: The method, apparatus, or non-transitory computer-readable medium of any of aspects 1 through 7, further including operations, features, circuitry, logic, means, or instructions, or any combination thereof for inputting the plurality of CA bits to a setup and hold circuit in response to initiating the CA clock and inputting the plurality of CA bits to the decoder in response to inputting the plurality of CA bits to the setup and hold circuit, where decoding the plurality of CA bits is in response to inputting the plurality of CA bits to the decoder.
Aspect 9: The method, apparatus, or non-transitory computer-readable medium of any of aspects 1 through 8, further including operations, features, circuitry, logic, means, or instructions, or any combination thereof for identifying the first command based at least in part on decoding the plurality of CA bits.

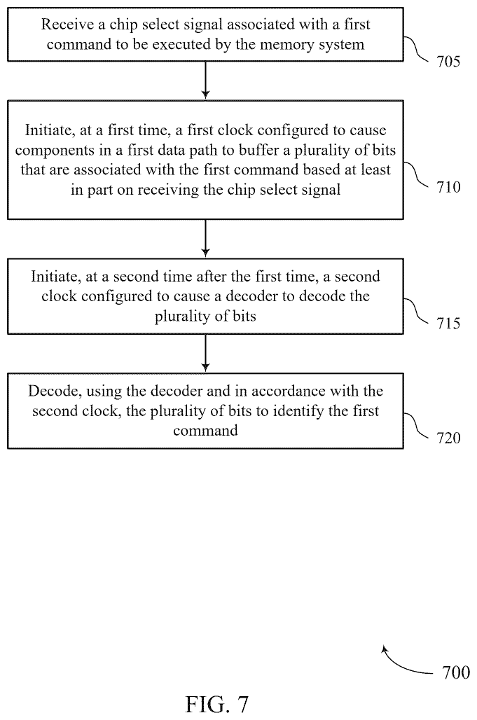

FIG. 7 shows a flowchart illustrating a method 700 that supports techniques for clock coordination with reduced power and latency at a memory system in accordance with examples as disclosed herein. The operations of method 700 may be implemented by a memory system or its components as described herein. For example, the operations of method 700 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 705, the method may include receiving a chip select signal associated with a first command to be executed by the memory system. In some examples, aspects of the operations of 705 may be performed by a command reception component 525 as described with reference to FIG. 5.

At 710, the method may include initiating, at a first time, a first clock configured to cause components in a first data path to buffer a plurality of bits that are associated with the first command based at least in part on receiving the chip select signal. In some examples, aspects of the operations of 710 may be performed by a clock management component 530 as described with reference to FIG. 5.

At 715, the method may include initiating, at a second time after the first time, a second clock configured to cause a decoder to decode the plurality of bits. In some examples, aspects of the operations of 715 may be performed by a clock management component 530 as described with reference to FIG. 5.

At 720, the method may include decoding, using the decoder and in accordance with the second clock, the plurality of bits to identify the first command. In some examples, aspects of the operations of 720 may be performed by a command reception component 525 as described with reference to FIG. 5.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:
Aspect 10: A method, apparatus, or non-transitory computer-readable medium including operations, features, circuitry, logic, means, or instructions, or any combination thereof for receiving a chip select signal associated with a first command to be executed by the memory system; initiating, at a first time, a first clock configured to cause components in a first data path to buffer a plurality of bits that are associated with the first command based at least in part on receiving the chip select signal; initiating, at a second time after the first time, a second clock configured to cause a decoder to decode the plurality of bits; and decoding, using the decoder and in accordance with the second clock, the plurality of bits to identify the first command.
Aspect 11: The method, apparatus, or non-transitory computer-readable medium of aspect 10, further including operations, features, circuitry, logic, means, or instructions, or any combination thereof for receiving a third clock associated with a host system, where a first clock path associated with the first clock and a second clock path associated with the second clock include respective branches of a clock tree associated with the third clock.
Aspect 12: The method, apparatus, or non-transitory computer-readable medium of aspect 11, where a difference between the first time and the second time corresponds to one or more unit intervals of the third clock.
Aspect 13: The method, apparatus, or non-transitory computer-readable medium of aspect 12, where the one or more unit intervals of the third clock include two unit intervals.
Aspect 14: The method, apparatus, or non-transitory computer-readable medium of any of aspects 11 through 13, further including operations, features, circuitry, logic, means, or instructions, or any combination thereof for delaying the second clock using a delay circuit configured to delay the second clock for one or more unit intervals of the third clock, where decoding the plurality of bits is based at least in part on inputting the second clock to the delay circuit.
Aspect 15: The method, apparatus, or non-transitory computer-readable medium of any of aspects 10 through 14, where the plurality of bits include command/address bits of the first command.
Aspect 16: The method, apparatus, or non-transitory computer-readable medium of any of aspects 10 through 15, where decoding the plurality of bits includes operations, features, circuitry, logic, means, or instructions, or any combination thereof for decoding, at a third time, a first subset of the plurality of bits and decoding, at a fourth time, a second subset of the plurality of bits, where a difference between the third time and the fourth time corresponds to at most two unit intervals of a third clock of the memory system.
Aspect 17: The method, apparatus, or non-transitory computer-readable medium of any of aspects 10 through 16, where decoding the plurality of bits includes operations, features, circuitry, logic, means, or instructions, or any combination thereof for buffering, in accordance with one or more first unit intervals of the first clock, a first subset of the plurality of bits; buffering, in accordance with one or more second unit intervals of the first clock, a second subset of the plurality of bits; receiving, by the decoder, the first subset and the second subset to obtain the plurality of bits; and decoding, at a third time, the plurality of bits, where the third time corresponds to a single edge of a third clock of the memory system.
Aspect 18: The method, apparatus, or non-transitory computer-readable medium of any of aspects 10 through 17, further including operations, features, circuitry, logic, means, or instructions, or any combination thereof for inputting the plurality of bits to a setup and hold circuit in response to initiating the first clock and inputting the plurality of bits to the decoder in response to inputting the plurality of bits to the setup and hold circuit, where decoding the plurality of bits is in response to inputting the plurality of bits to the decoder.

It should be noted that the aspects described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components. ” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
receive a chip select signal associated with a first command to be executed by the memory system;
initiate, at a first time, a command/address (CA) clock configured to cause components of a CA path to buffer a plurality of CA bits received over a CA channel;
initiate, at a second time after the first time, a decoding clock configured to cause a decoder to decode the plurality of CA bits; and
decode, using the decoder and in accordance with the decoding clock, the plurality of CA bits to identify the first command.

2. The memory system of claim 1, wherein the processing circuitry is further configured to cause the memory system to:
receive a clock associated with a host system, wherein a first clock path associated with the CA clock and a second clock path associated with the decoding clock comprise respective branches of a clock tree associated with the clock.

3. The memory system of claim 2, wherein a difference between the first time and the second time corresponds to one or more unit intervals of the received clock.

4. The memory system of claim 3, wherein the one or more unit intervals of the received clock comprise two unit intervals.

5. The memory system of claim 2, wherein the processing circuitry is further configured to cause the memory system to:
delay the decoding clock using a delay circuit configured to delay the decoding clock for one or more unit intervals of the received clock, wherein decoding the plurality of CA bits is based at least in part on inputting the decoding clock to the delay circuit.

6. The memory system of claim 1, wherein, to decode the plurality of CA bits, the processing circuitry is configured to cause the memory system to:
decode, at a third time, a first subset of the plurality of CA bits; and
decode, at a fourth time, a second subset of the plurality of CA bits, wherein a difference between the third time and the fourth time corresponds to at most two unit intervals of a clock of the memory system.

7. The memory system of claim 1, wherein, to decode the plurality of CA bits, the processing circuitry is configured to cause the memory system to:
buffer, in accordance with one or more first unit intervals of the CA clock, a first subset of the plurality of CA bits;
buffer, in accordance with one or more second unit intervals of the CA clock, a second subset of the plurality of CA bits;
receive, by the decoder, the first subset and the second subset to obtain the plurality of CA bits; and
decode, at a third time, the plurality of CA bits, wherein the third time corresponds to a single edge of a clock of the memory system.

8. The memory system of claim 1, wherein the processing circuitry is further configured to cause the memory system to:
input the plurality of CA bits to a setup and hold circuit in response to initiating the CA clock; and
input the plurality of CA bits to the decoder in response to inputting the plurality of CA bits to the setup and hold circuit, wherein decoding the plurality of CA bits is in response to inputting the plurality of CA bits to the decoder.

9. The memory system of claim 1, wherein the processing circuitry is further configured to cause the memory system to:
identify the first command based at least in part on decoding the plurality of CA bits.

10. A memory system, comprising:
one or more memory devices; and
processing circuitry coupled with the one or more memory devices and configured to cause the memory system to:
receive a chip select signal associated with a first command to be executed by the memory system;
initiate, at a first time, a first clock configured to cause components in a first data path to buffer a plurality of bits that are associated with the first command based at least in part on receiving the chip select signal;
initiate, at a second time after the first time, a second clock configured to cause a decoder to decode the plurality of bits; and
decode, using the decoder and in accordance with the second clock, the plurality of bits to identify the first command.

11. The memory system of claim 10, wherein the processing circuitry is further configured to cause the memory system to:
receive a third clock associated with a host system, wherein a first clock path associated with the first clock and a second clock path associated with the second clock comprise respective branches of a clock tree associated with the third clock.

12. The memory system of claim 11, wherein a difference between the first time and the second time corresponds to one or more unit intervals of the third clock.

13. The memory system of claim 12, wherein the one or more unit intervals of the third clock comprise two unit intervals.

14. The memory system of claim 11, wherein the processing circuitry is further configured to cause the memory system to:
delay the second clock using a delay circuit configured to delay the second clock for one or more unit intervals of the third clock, wherein decoding the plurality of bits is based at least in part on inputting the second clock to the delay circuit.

15. The memory system of claim 10, wherein the plurality of bits comprise command/address bits of the first command.

16. The memory system of claim 10, wherein, to decode the plurality of bits, the processing circuitry is configured to cause the memory system to:
decode, at a third time, a first subset of the plurality of bits; and
decode, at a fourth time, a second subset of the plurality of bits, wherein a difference between the third time and the fourth time corresponds to at most two unit intervals of a third clock of the memory system.

17. The memory system of claim 10, wherein, to decode the plurality of bits, the processing circuitry is configured to cause the memory system to:
buffer, in accordance with one or more first unit intervals of the first clock, a first subset of the plurality of bits;
buffer, in accordance with one or more second unit intervals of the first clock, a second subset of the plurality of bits;
receive, by the decoder, the first subset and the second subset to obtain the plurality of bits; and
decode, at a third time, the plurality of bits, wherein the third time corresponds to a single edge of a third clock of the memory system.

18. The memory system of claim 10, wherein the processing circuitry is further configured to cause the memory system to:
input the plurality of bits to a setup and hold circuit in response to initiating the first clock; and
input the plurality of bits to the decoder in response to inputting the plurality of bits to the setup and hold circuit, wherein decoding the plurality of bits is in response to inputting the plurality of bits to the decoder.

19. A method by a memory system, comprising:
receiving a chip select signal associated with a first command to be executed by the memory system;
initiating, at a first time, a command/address (CA) clock configured to cause components of a CA path to buffer a plurality of CA bits received over a CA channel;
initiating, at a second time after the first time, a decoding clock configured to cause a decoder to decode the plurality of CA bits; and
decoding, using the decoder and in accordance with the decoding clock, the plurality of CA bits to identify the first command.

20. The method of claim 19, further comprising:
receiving a clock associated with a host system, wherein a first clock path associated with the CA clock and a second clock path associated with the decoding clock comprise respective branches of a clock tree associated with the clock.
